(19) United States
(12) Patent Application Publication
(10) Pub. No.: US 2026/0304637 A1
(43) Pub. Date: Oct. 1, 2026

(54) CONDUCTIVE FILM FORMING APPARATUS AND CONDUCTIVE FILM FORMING METHOD

(71) Applicant: SHIBAURA MECHATRONICS CORPORATION, Kanagawa (JP)

(72) Inventors: Kota ASAOKA, Kanagawa (JP); Tatsumi KOBAYASHI, Kanagawa (JP); Yasuaki MIYAMOTO, Kanagawa (JP); Hitoshi AOYAGI, Kanagawa (JP)

(21) Appl. No.: 19/577,977

(22) Filed: Mar. 25, 2026

(30) Foreign Application Priority Data
Mar. 31, 2025 (JP) 2025-059810

(51) Int. Cl. H05K 3/12

(52) U.S. Cl. CPC H05K 3/125; H05K 2203/013

(57) ABSTRACT

According to one embodiment of the present disclosure, a conductive film forming apparatus includes: a drum including an inner peripheral surface that forms a hollow structure, and a holding unit that is provided in the inner peripheral surface and holds a substrate; an inkjet head that ejects conductive ink; a rotation mechanism that rotates the drum; and a control unit that controls the inkjet head to eject the conductive ink to a plurality of through micro-holes formed in the substrate, and after ejection of the conductive ink by the inkjet head is completed, controls the rotation mechanism to rotate the drum.

### CROSS REFERENCES TO RELATED APPLICATIONS

This application is based on and claims priority from Japanese Patent Application No. 2025-059810, filed on Mar. 31, 2025, with the Japan Patent Office, the disclosure of which is incorporated herein in its entirety by reference.

### TECHNICAL FIELD

The present disclosure relates to a conductive film forming apparatus and a conductive film forming method.

### BACKGROUND

There is a technology, in which an inkjet head ejects conductive ink to a glass substrate with fine through holes formed therein (through glass via (TGV)), thereby coating the through holes with the conductive ink. As a result, for example, through electrodes are formed. See, for example, Japanese Patent Laid-Open Publication No. 2017-143140.

### SUMMARY

However, the diameter of a through hole formed in the TGV substrate may be equal or smaller than the diameter of a single drop of the conductive ink ejected from the inkjet head (e.g., a conductive ink droplet). FIG. 11 is a sectional view of the substrate illustrating the relationship between the through hole and the conductive ink droplet. For example, as illustrated in FIG. 11, an inkjet head ejects conductive ink 94 to a glass substrate 90, which includes two main surfaces 91 and 92 and a through hole 93 formed to penetrate from the main surface 91 to the main surface 92, from the main surface 91 side. However, there may be a case where the conductive ink 94 remains on the main surface 91 side in the through hole 93 without moving to the main surface 92 side, and thus, a conductive film, which is uniform from the main surface 91 side to the main surface 92 side, may not be formed.

The present disclosure has been proposed to solve the problem above, and provides a conductive film forming apparatus and a conductive film forming method, which may form a uniform conductive film in a through hole formed in a substrate.

According to an aspect of the present disclosure, a conductive film forming apparatus includes: a drum including an inner peripheral surface that forms a hollow structure, and a holding unit that is provided in the inner peripheral surface and holds a substrate; an inkjet head that ejects conductive ink; a rotation mechanism that rotates the drum; and a control unit that controls the inkjet head to eject the conductive ink to a plurality of through micro-holes formed in the substrate, and after ejection of the conductive ink by the inkjet head is completed, controls the rotation mechanism to rotate the drum.

According to another aspect of the present disclosure, a conductive film forming method includes: ejecting conductive ink to a plurality of through micro-holes formed in a plate-shaped substrate including a first surface and a second surface opposite to the first surface, from a side of the first surface; and moving the substrate such that a force is applied to the conductive ink adhering to the substrate in a direction from the first surface toward the second surface.

According to an aspect of the present disclosure, it is possible to provide a conductive film forming apparatus and a conductive film forming method, which may form a uniform conductive film in a through hole formed in a substrate.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating the configuration of a conductive film forming apparatus according to a first embodiment.

FIG. 2 is a schematic view illustrating a state where substrates are held by holding units of the conductive film forming apparatus according to the first embodiment.

FIG. 3 is a sectional view illustrating the cross section of a portion of a substrate according to the first embodiment.

FIG. 4 is a sectional view illustrating a state of the substrate to which conductive ink has been ejected, according to an embodiment.

FIG. 5 is a sectional view illustrating a state of the substrate after a centrifugal force is applied to the conductive ink ejected to the substrate, according to an embodiment.

FIG. 6 is a sectional view illustrating another state of the substrate after the centrifugal force is applied to the conductive ink ejected to the substrate, according to an embodiment.

FIG. 7 is a schematic view illustrating the configuration of a conductive film forming apparatus according to a second embodiment.

FIG. 8 is a schematic view illustrating the shape of a drum according to a modification.

FIG. 9 is a schematic view illustrating the shape of a drum according to another modification.

FIG. 10 is a plan view of a drum according to a modification.

FIG. 11 is a sectional view of a substrate illustrating a relationship between a through hole and a conductive ink droplet.

### DESCRIPTION OF EMBODIMENTS

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of the conductive film forming apparatus and the conductive film forming method of the present disclosure will be described in detail with reference to the accompanying drawings. In the embodiments, descriptions will be made assuming a case where an inkjet head ejects conductive ink to fine through holes (through micro-holes) formed in a glass substrate, thereby forming a uniform conductive film in the through micro-holes. However, the inkjet head may eject the conductive ink to fine through holes formed in substrates other than the glass substrate, and perform the same process as described herein below, thereby forming a uniform conductive film in the fine through holes.

### First Embodiment

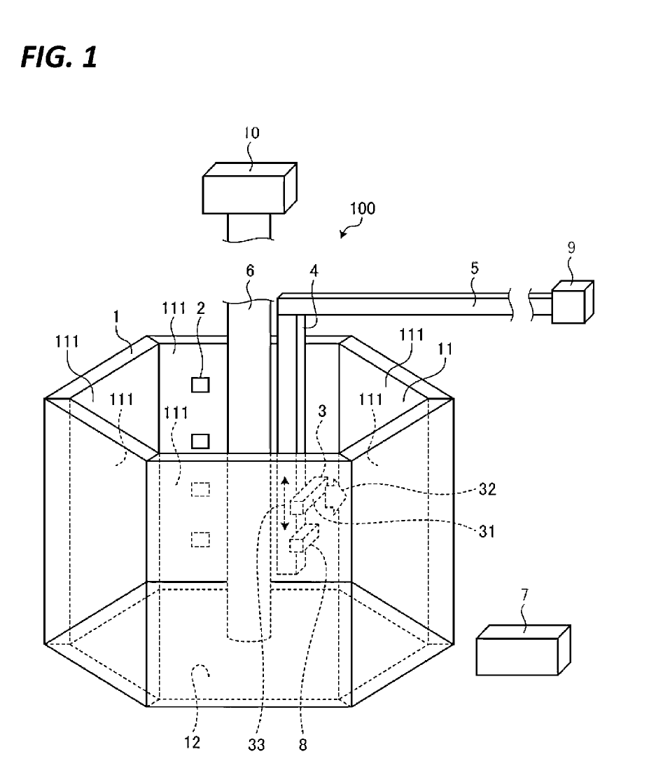

FIG. 1 is a schematic view illustrating the configuration of a conductive film forming apparatus according to a first embodiment. As illustrated in FIG. 1, a conductive film forming apparatus 100 includes a drum 1, a holding unit 2, an inkjet head 3, a head lifting rail 4, a lifting rail holding mechanism 5, a rotary shaft 6, a control device 7, movement drive mechanisms 8 and 9, and a rotation drive mechanism 10.

In the descriptions and the claims of the present disclosure, "up" indicates the direction vertically away from the installation surface of the conductive film forming apparatus (e.g., the floor surface of a factory), and "down" indicates the direction opposite to "up."

The drum 1 has a hexagonal prism shape, in which the top surface thereof is open, and the interior is formed as an internal cavity (hollow). The drum 1 includes an inner peripheral surface (e.g., an inner wall surface) 11 and a bottom surface 12, and has a prismatic shape in which one end side (e.g., the lower side) thereof is covered by the bottom surface 12. The inner peripheral surface 11 is configured with six planes 111. Each of the six planes 111 is provided in an upright position to extend vertically from each of the six sides of the bottom surface 12. The bottom surface 12 is spaced from the floor surface of the factory where the conductive film forming apparatus 100 is installed, by a predetermined distance, and is parallel to the floor surface.

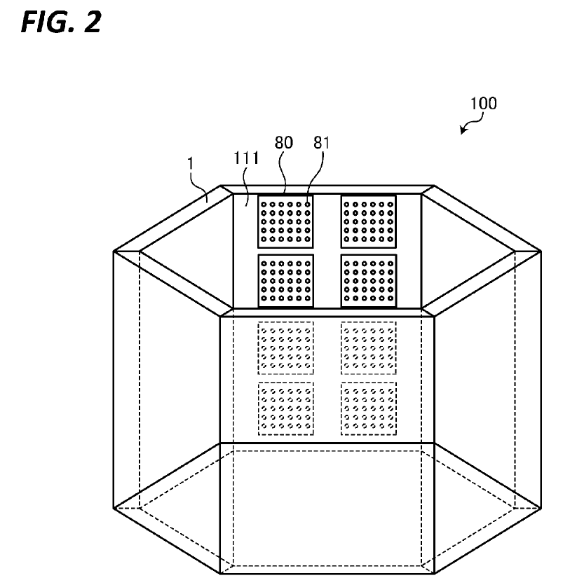

A plurality of holding units 2 is provided on each of the six planes 111. Each holding unit 2 holds a substrate 80 (see, e.g., FIG. 2). For example, the holding unit 2 may be configured with a shelf unit on which the substrate 80 is disposed. By disposing the substrate 80 on the shelf unit, the shelf unit holds the substrate 80. Alternatively, the holding unit 2 may be configured with an adsorption unit that holds one of the two main surfaces of the substrate 80 by adsorption. When the holding unit is configured with the adsorption unit, the adsorption unit may adsorb a portion of one of the main surfaces of the substrate 80 where through micro-holes 81 to be described herein later are not arranged. Hereinafter, in the present embodiment, the holding unit 2 will be described as a mechanism that holds one of the main surfaces of the substrate 80 by adsorption.

In the example of FIG. 1, on one plane 111, four holding units 2 are arranged in the up-down direction to form a column, and two columns thereof are arranged in a direction orthogonal to the direction in which each column extends. That is, eight holding units 2 are provided on one plane 111. FIG. 1 illustrates the holding units 2 arranged in one column among the eight holding units 2 provided on one plane 111, and omits the illustration of the holding units 2 arranged in the other column on the one plane 111 and the plurality of holding units 2 provided on the remaining five planes 111 (e.g., 40 (8×5) holding units 2). Here, the number and arrangement of holding units 2 provided in the conductive film forming apparatus 100 are not limited to those described above. Further, while descriptions have been made on the case where a single holding unit 2 holds a single substrate 80, a single holding unit 2 may hold a plurality of substrates 80. For example, a single (common) holding unit 2 may be provided across all of the six planes 111 to hold one or a plurality of substrates 80 on each plane 111.

FIG. 2 is a schematic view illustrating the state where the substrates are held by the holding units of the conductive film forming apparatus according to the first embodiment. FIG. 2 illustrates only the drum 1 and the substrates 80 held on one plane 111 among the plurality of components of the conductive film forming apparatus 100, and omits the illustration of the other components. As illustrated in FIG. 2, on one plane 111, eight holding units 2 hold eight substrates 80. On the remaining five planes 111 as well, a total of 40 holding units 2 hold the substrates 80, respectively (not illustrated). Accordingly, in the present embodiment, eight holding units 2 hold eight substrates 80 in each angular range of 60 degrees (360 degrees/6). The holding units 2 support the substrates 80 such that the inkjet head 3 to be described herein later may eject the conductive ink to the through micro-holes 81 to be described herein later.

In the present embodiment, descriptions will be made assuming an example where the substrate 80 is a glass substrate. A plurality of through micro-holes 81 is formed in the substrate 80, which is a rectangular glass substrate (through glass via (TGV)). That is, a plurality of through micro-holes 81 is formed in the substrate 80 to penetrate from one of the two main surfaces to the other. In the example of FIG. 2, in the substrate 80, five through micro-holes 81 are arranged in a column direction, and six columns thereof are arranged in a row direction. That is, in the example of FIG. 2, 30 (5×6) through micro-holes 81 are formed in each substrate 80. However, the number and arrangement of the through micro-holes 81 formed in each substrate 80 are not limited thereto.

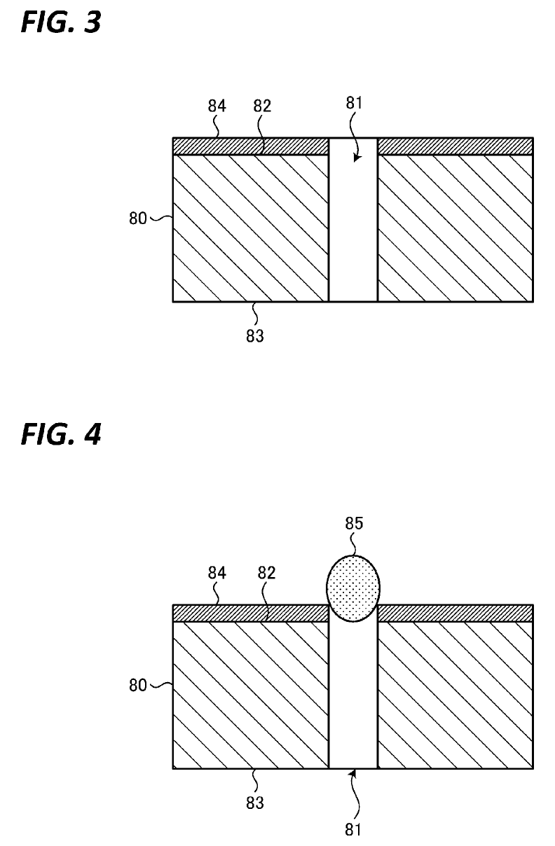

FIG. 3 is a sectional view illustrating an example of the cross section of a portion of the substrate according to the first embodiment. As illustrated in FIG. 3, the substrate 80 includes the two main surfaces (e.g., the main surfaces 82 and 83). The main surface 82 is an example of a first surface (e.g., a front surface). The main surface 83 is an example of a second surface (e.g., a back surface). The through micro-hole 81 is formed in the substrate 80 to penetrate from the main surface 82 to the main surface 83. As illustrated in FIG. 3, a liquid repellent layer 84 is formed on the main surface 82 of the substrate 80. The liquid repellent layer 84 is not formed inside the through micro-hole 81. That is, the liquid repellent layer 84 is formed in the entire region of the main surface 82 of the substrate 80, excluding the through micro-hole 81. The liquid repellent layer 84 has the function of repelling the conductive ink. As to the liquid repellent processing, the liquid repellent layer 84 is formed through spin-coating before forming the through micro-hole 81 in the substrate 80, and then, the through micro-hole 81 is opened, so that the liquid repellent layer 84 may be formed only on the main surface 82 of the substrate 80.

The holding unit 2 adsorbs and holds the main surface 83 side of the substrate 80 such that the main surfaces 82 and 83 become parallel to the plane 111 on which the holding unit 2 is provided. Accordingly, the main surfaces 82 and 83 of the substrate 80 held by the holding unit 2 are positioned in parallel to the vertical plane. In this way, the holding unit 2 holds the substrate 80 such that the inkjet head 3 to be described herein later may eject the conductive ink to the through micro-hole 81 from the main surface 82 side.

Returning to the descriptions of FIG. 1, the inkjet head 3 ejects the conductive ink. The inkjet head 3 includes an ejection surface 31. The ejection surface 31 is provided with a plurality of nozzles (holes). The conductive ink is supplied from a tank (not illustrated) into the inkjet head 3, and is extruded from the nozzles of the inkjet head 3, so that the inkjet head 3 ejects the conductive ink from the ejection surface 31 in the direction indicated by an arrow 32. In the present embodiment, the ejection surface 31 is parallel to the vertical plane, and the plurality of nozzles are provided in a row at equal intervals along the length direction of the ejection surface 31. In the present embodiment, the pitch (interval) between two adjacent nozzles formed in the ejection surface 31 coincides with the interval between two adjacent through micro-holes 81 formed in the substrate 80. That is, the inkjet head 3 may eject the conductive ink to the same number of through micro-holes 81 as the number of nozzles formed in the ejection surface 31. Alternatively, when a value equal to an integer multiple of the pitch between the nozzles coincides with the interval between two adjacent through micro-holes 81 formed in the substrate 80, the conductive ink may be ejected using, among the plurality of nozzles of the inkjet head 3, a number of nozzles calculated by dividing the number of the plurality of nozzles of the inkjet head 3 by the integer above to make the pitch between the nozzles coincide with the interval of the through micro-holes 81.

The head lifting rail 4 extends in the up-down direction. The head lifting rail 4 supports the inkjet head 3 such that the inkjet head 3 is movable along the rail extending in the up-down direction.

The lifting rail holding mechanism 5 holds the head lifting rail 4. The lifting rail holding mechanism 5 is a member with a slender square prism shape, and is fixed with respect to, for example, a support frame of the conductive film forming apparatus 100. Further, the upper end of the head lifting rail 4 is connected to one end of the lower surface of the lifting rail holding mechanism 5. The other end of the lifting rail holding mechanism 5 is connected to the movement drive mechanism 9.

The rotary shaft 6 is a cylindrical member that extends in the up-down direction. The lower end of the rotary shaft 6 is connected to the center of the hexagonal bottom surface 12. That is, the lengths of perpendicular lines drawn from the location where the rotary shaft 6 is connected to the bottom surface 12 (e.g., the center of the rotary shaft 6) to the respective midpoints of the six sides of the bottom surface 12 are all equal. The upper end of the rotary shaft 6 is connected to the rotation drive mechanism 10. As the rotary shaft 6 is rotated by the rotation drive mechanism 10, the drum 1 rotates.

The control device 7 includes a CPU (central processing unit), a ROM (read only memory), a RAM (random access memory), an HDD (hard disk drive), and a communication interface. These components are connected to each other via an internal bus.

The CPU executes various processes while using the storage area of the RAM as an area for temporarily storing data that are used for the various processes. The ROM and the HDD store programs for executing the various processes, or for example, various databases and tables that are used when the various processes are executed. The CPU executes the various processes by executing the programs stored in the ROM and the HDD. Further, the CPU executes the various processes by using, for example, the various databases and tables stored in the ROM and the HDD. The communication interface may communicate with the inkjet head 3, the movement drive mechanisms 8 and 9, and the rotation drive mechanism 10. Thus, the CPU may control each of the inkjet head 3, the movement drive mechanisms 8 and 9, and the rotation drive mechanism 10. That is, the CPU may transmit instructions to each of the inkjet head 3, the movement drive mechanisms 8 and 9, and the rotation drive mechanism 10. For example, the control device 7 is an example of a controller.

The movement drive mechanism 8 includes, for example, a motor or a gear, receives instructions from the control device 7, and moves the inkjet head 3 in the up-down direction along the head lifting rail 4 based on the received instructions. The movement drive mechanism 8 may be any mechanism that moves the drum 1 and the inkjet head 3 relatively in the up-down direction, and may be configured to move the drum 1 in the up-down direction or to move both the drum 1 and the inkjet head 3 in the up-down direction. The movement drive mechanism 8 is an example of a movement mechanism.

The movement drive mechanism 9 includes, for example, a motor or a gear, and holds the head lifting rail 4 (and the inkjet head 3) to be movable in a direction orthogonal to the direction of an arrow 33 via the lifting rail holding mechanism 5. The movement drive mechanism 9 receives instructions from the control device 7, and based on the received instructions, moves the head lifting rail 4 (and the inkjet head 3) in the direction orthogonal to the direction of the arrow 33 via the lifting rail holding mechanism 5. The movement drive mechanism 9 is also an example of a movement mechanism.

The rotation drive mechanism 10 includes, for example, a motor, and rotates the rotary shaft 6 under the control of the control device 7. The rotation drive mechanism 10 is an example of a rotation mechanism.

An example of the configuration of the conductive film forming apparatus 100 according to the first embodiment has been described. Next, an example of the operation of the conductive film forming apparatus 100 will be described.

First, the substrates 80 are held by the holding units 2 over the entire inner peripheral surfaces 11. For example, the substrates 80 may be manually held on all of the holding units 2 by an operator (e.g., a user) of the conductive film forming apparatus 100. Alternatively, the substrates 80 may be held on all of the holding units 2 by a robot.

The control device 7 of the conductive film forming apparatus 100, first, transmits an instruction to the rotation drive mechanism 10 to position the drum 1 at a first rotation position. Accordingly, the drum 1 is positioned at a rotation position (e.g., the first rotation position) where the conductive ink may be ejected from the inkjet head 3 to the eight substrates 80 held on one specific plane 111 among the six planes 111. This control is unnecessary when the rotation position of the drum 1 is already set to the first rotation position before the control above is performed.

Then, the control device 7 controls the movement drive mechanisms 8 and 9 and the inkjet head 3, such that the conductive ink is ejected to all of the through micro-holes 81 of the eight substrates 80, at the first rotation position.

Here, in the ejection surface 31 of the inkjet head 3, the width of the region where the plurality of nozzles are formed (e.g., the dimension in the direction orthogonal to the arrow 33) is smaller than the sum of widths of two substrates 80 arranged in the width direction of the plane 111 and the width between the two substrates 80. Thus, the inkjet head 3 repeatedly ejects the conductive ink from the plurality of nozzles formed in the ejection surface 31 toward the substrates 80, while moving in the up-down direction and in the direction orthogonal to the up-down direction (e.g., the width direction of the plane 111), so that the conductive ink may be ejected to all of the through micro-holes 81 of the eight substrates 80 held on the one specific plane 111. Hereinafter, the eight substrates 80 held on one plane 111 may be collectively referred to as a "substrate group." A plurality of inkjet heads 3 may be provided to cover the entire substrate group, and may eject the conductive ink to all of the through micro-holes 81 included in the substrate group without moving. Alternatively, a plurality of inkjet heads 3 may be provided to cover the entire width of the substrate group in the width direction of the plane 111, and may eject the conductive ink to all of the through micro-holes 81 included in the substrate group by merely moving in the up-down direction.

At the first rotation position, the control device 7 transmits an instruction to the movement drive mechanism 8 to move the inkjet head 3 in the up-down direction at a predetermined speed. Accordingly, the movement drive mechanism 8 positions the inkjet head 3 to face the through micro-holes 81 in an order starting from the through micro-holes 81 arranged at the uppermost position, and causes the inkjet head 3 to move downward while ejecting the conductive ink. Further, the control device 7 moves the inkjet head 3 to the uppermost position described above before the application is started.

Next, the control device 7 outputs a signal to the movement drive mechanism 8 to position the inkjet head 3 at the uppermost position again, and also outputs a signal to the movement drive mechanism 9 to move the lifting rail holding mechanism 5 along the width direction of the plane 111. Accordingly, the inkjet head 3 is positioned to face a substrate 80 to which the conductive ink has not yet been applied, in the substrate group. The movement drive mechanism 8 causes the inkjet head 3 to move downward again while ejecting the conductive ink.

The control device 7 repeatedly performs the process described above until the ejection of the conductive ink to all of the through micro-holes 81 of the substrate group at the first rotation position is completed. As a result, at the first rotation position, the ejection of the conductive ink to all of the through micro-holes 81 of the eight substrates 80 is completed.

Here, as described above, the inner peripheral surface 11 configured with the six planes 111 has a hexagonal shape in plan view. Thus, a rotation position located by rotating the drum 1 by 60 degrees in a predetermined direction from the first rotation position is set as a second rotation position, a rotation position located by rotating the drum 1 by 120 degrees in the predetermined direction from the first rotation position is set as a third rotation position, a rotation position located by rotating the drum 1 by 180 degrees in the predetermined direction from the first rotation position is set as a fourth rotation position, a rotation position located by rotating the drum 1 by 240 degrees in the predetermined direction from the first rotation position is set as a fifth rotation position, and a rotation position located by rotating the drum 1 by 300 degrees in the predetermined direction from the first rotation position is set as a sixth rotation position.

Then, the control device 7 controls the rotation drive mechanism 10 to rotate the drum 1 in the predetermined direction at a first rotational speed, and to stop the drum 1 at each rotation position in the order of the second to sixth rotation positions. That is, the control device 7 causes the rotation drive mechanism 10 to rotate the drum 1 in the predetermined direction at the first rotational speed from an N-th rotation position (N is an integer of 1 to 5) to an (N+1)-th rotation position, and to stop the drum 1 at the (N+1)-th rotation position. Then, in the state where the drum 1 is stopped at each of the second to sixth rotation positions, the control device 7 performs the same process as performed at the first rotation position. As a result, at each of the second to sixth rotation positions, the ejection of the conductive ink to all of the through micro-holes 81 of the eight substrates 80 is completed.

Through the process described above, the ejection of the conductive ink to all of the through micro-holes 81 provided in all of the substrates 80 held on the six planes 111 is completed. An example of the state of the conductive ink adhering to the substrates 80 at this time will be described. FIG. 4 is a sectional view illustrating the state of a substrate to which the conductive ink has been ejected, according to an embodiment. As illustrated in FIG. 4, since the diameter of the conductive ink 85 ejected to the substrate 80 is substantially equal to the diameter of the through micro-hole 81, the conductive ink 85 remains on the main surface 82 side without moving to the main surface 83 side, in the through micro-hole 81. Further, since the liquid repellent layer 84 is formed on the main surface 82 side, the conductive ink 85 may remain on the through micro-hole 81 without, for example, spreading over the liquid repellent layer 84.

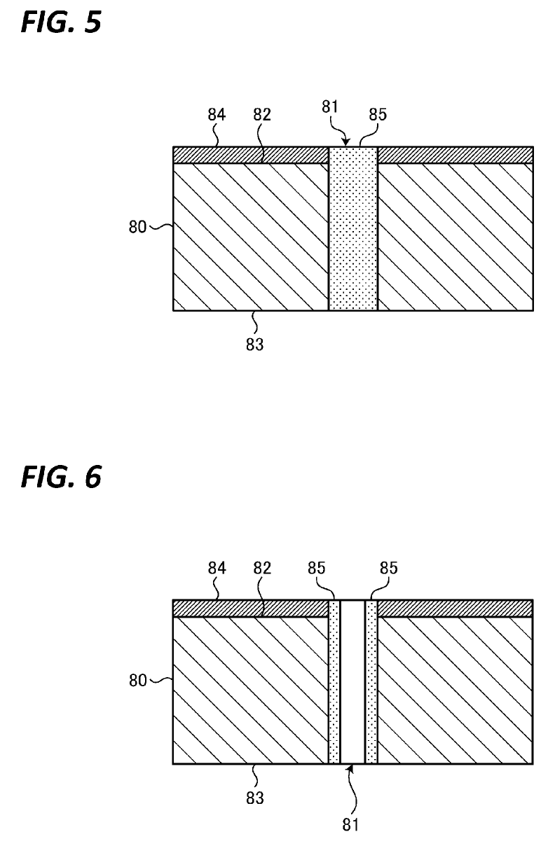

Next, the control device 7 controls the rotation drive mechanism 10 to rotate the drum 1 at a high speed. For example, the control device 7 causes the rotation drive mechanism 10 to rotate the drum 1 at a second rotational speed faster than the first rotational speed. The rotation direction at this time may be the same as or opposite to the predetermined direction described above. The drum 1 may be rotated in the predetermined direction a predetermined number of times, and then, may be rotated in the opposite direction a predetermined number of times. As a result, a centrifugal force acts on the conductive ink 85 adhering to the substrate 80 in the direction from the main surface 82 toward the main surface 83 of the substrate 80. For example, when the angular velocity corresponding to the second rotational speed is ω [rad/s], the mass of the conductive ink 85 adhering to the substrate 80 is m [kg], and the distance from the rotary shaft 6 to the main surface 82 of the substrate 80 (the radius of the circular motion of the conductive ink 85) is r [m], a centrifugal force of mr ω² [N] acts on the conductive ink 85 adhering to the substrate 80. As a result, as illustrated in FIG. 5, the conductive ink 85 is filled into the through micro-hole 81 up to the main surface 83 side, for example, up to the deep portion of the through micro-hole 81. Alternatively, as illustrated in FIG. 6, the conductive ink 85 comes into the state of adhering to the inner wall surface of the substrate 80 that forms the through micro-hole 81, reaching the deep portion of the through micro-hole 81. Thus, when the conductive ink 85 is fired, a uniform conductive film may be formed in the through micro-hole 81. The conductive film may be used as a through electrode or as a seed when performing plating processing.

Here, descriptions will be made on a case where a conductive material (e.g., a metal) is introduced into through micro-holes formed in a glass substrate by sputtering to form through electrodes. First, a conductor film (e.g., a metal film) is formed by sputtering on the entire region of the surface of the glass substrate in which through micro-holes are formed. Then, the conductor film formed on the surface is removed by, for example, chemical mechanical polishing (CMP). Since the conductive film needs to be formed only in the inside of the through micro-holes to form through electrodes, the conductor film on the surface is removed.

However, the technique of introducing the conductive material into the through micro-holes formed in the glass substrate by sputtering to form through electrodes has four significant problems. As to the first problem, in the sputtering, since sputtered particles do not necessarily travel perpendicularly to the glass substrate, a relatively large amount of film is deposited at a shallow portion of each through micro-hole, while the amount of film deposited at a deep portion thereof decreases. As to the second problem, in the sputtering, since the conductive film may not be selectively formed in the through micro-holes, the conductive material that is the material for the conductive film is consumed in a relatively large amount, increasing running costs. As to the third problem, since the sputtering is performed in the vacuum state, the apparatus that performs the sputtering becomes large and expensive. As to the fourth problem, since most of the formed conductor film is removed, the amount of material to be discarded increases, and since chemical liquids are used during the CMP, waste liquid is generated, which increases environmental load.

Meanwhile, in the present embodiment, the conductive ink ejected by the inkjet head 3 may be filled into a relatively deeper portion of the through micro-hole 81. Thus, when the conductive ink is fired, a uniform conductive film may be formed in the through micro-hole 81, so that a through electrode having uniformity, low resistance, and high reliability may be formed. Further, in the present embodiment, the conductive ink is selectively ejected to the through micro-holes 81 by the inkjet head 3, so that the increase in amount of material to be discarded when filling the through micro-holes 81 may be suppressed, and low cost and low environmental load may be implemented.

The conductive film forming apparatus 100 according to the first embodiment has been described. As described above, the conductive film forming apparatus 100 includes: the drum 1 including the inner peripheral surface 11 that forms the hollow structure, and the holding unit 2 provided on the inner peripheral surface 11 to hold the substrate 80; the inkjet head 3 that ejects the conductive ink; the rotation mechanism including the rotation drive mechanism 10 that rotates the drum 1, and the rotary shaft 6; and the control device 7 that controls the inkjet head 3 to eject the conductive ink to the plurality of through micro-holes 81 formed in the substrate 80, and after the ejection of the conductive ink by the inkjet head 3 is completed, controls the rotation mechanism to rotate the drum 1.

The conductive film forming apparatus 100 further includes the movement mechanism that relatively moves the inkjet head 3 with respect to the drum 1 in a direction different from the direction of the movement by the rotation mechanism. The control device 7 causes the movement mechanism to relatively move the inkjet head 3 with respect to the drum 1 such that the inkjet head 3 may eject the conductive ink to all of the plurality of through micro-holes 81 formed in the substrate 80 held by the holding unit 2, and by relatively moving the inkjet head 3 with respect to the drum 1, completes the ejection of the conductive ink.

Further, a plurality of holding units 2 is provided on the inner peripheral surface 11. A plurality of substrates 80 forms a substrate group in each range of the inner peripheral surface 11 that corresponds to the predetermined angle (e.g., 60 degrees). The predetermined angle is set in advance in the rotation direction of the drum 1. A plurality of substrate groups is arranged in the rotation direction of the drum 1. The control device 7 repeatedly controls the rotation mechanism to rotate the drum 1 by the predetermined angle at the first rotational speed, and then, stop the drum 1 such that when the drum 1 stops, the ejection surface 31 of the inkjet head 3 faces the substrate group corresponding to the predetermined angle. Further, the control device 7 controls the rotation mechanism and the inkjet head 3 such that each time the drum 1 stops, the conductive ink is ejected to the plurality of through micro-holes of the substrate group, and after the ejection of the conductive ink to all of the substrate groups is completed, causes the rotation mechanism to rotate the drum 1 at the second rotational speed faster than the first rotational speed.

Further, the liquid repellent layer 84 is provided on the main surface 82 of the substrate 80 that faces the inkjet head 3, and the control device 7 causes the inkjet head 3 to eject the conductive ink from the liquid repellent layer 84 side to the plurality of through micro-holes 81 of the substrate 80 on which the liquid repellent layer 84 is provided.

Further, the conductive film forming apparatus 100 performs a conductive film forming method, which ejects the conductive ink from the main surface 82 side to the plurality of through micro-holes 81 of the plate-shaped substrate 80 including the main surface 82 and the main surface 83 opposite to the main surface 82, and moves the substrate 80 such that a force is applied to the conductive ink adhering to the substrate 80 in the direction from the main surface 82 toward the main surface 83.

According to the conductive film forming apparatus 100 of the first embodiment, as described above, a uniform conductive film may be formed in the through micro-holes 81.

In the first embodiment, descriptions have been made on the case where the conductive film forming apparatus 100 ejects the conductive ink to the plurality of through micro-holes 81 formed in the eight substrates 80 held on each of the six planes 111 of the drum 1, using one inkjet head 3, one head lifting rail 4, and the rotation drive unit. However, the conductive film forming apparatus 100 may eject the conductive ink to the plurality of through micro-holes 81 formed in the substrate groups held on the six planes 111, respectively, using six inkjet heads 3 and six head lifting rails 4 that correspond to the six planes 111, respectively, without rotating the drum 1.

In the first embodiment, for example, the conductive film forming apparatus 100 sets the first to sixth rotation positions as the positions where the planes 111 and the ejection surface 31 of the inkjet head 3 become parallel to each other. However, the present disclosure is not limited thereto. As long as the conductive ink may be ejected from the inkjet head 3 to the through micro-holes 81, the position for stopping the drum 1 to perform the ejection from the inkjet head 3 may not be the position where the ejection surface 31 of the inkjet head 3 becomes parallel to the plane 111.

In the first embodiment, for example, the conductive film forming apparatus 100 controls the movement drive mechanism 9 to move the head lifting rail 4 and the inkjet head 3 along the width direction of the plane 111, thereby positioning the inkjet head 3 to face the substrate 80 to which the conductive ink has not yet been applied. However, the present disclosure is not limited thereto. For example, the drum 1 may be rotated, thereby positioning the inkjet head 3 to face the substrate 80 to which the conductive ink has not yet been applied. In this case, the angle of the inkjet head 3 (e.g., the rotation angle relative to a line extending vertically through the longitudinal center of the inkjet head 3) may be adjusted by the movement drive mechanism 9.

In the first embodiment, for example, the conductive film forming apparatus 100 rotates the drum 1 at the second rotational speed after the application of the conductive ink by the inkjet head 3. However, the present disclosure is not limited thereto. After completing the application of the conductive ink and the rotation of the drum 1 at the second rotational speed, the application of the conductive ink and the rotation of the drum 1 at the second rotational speed may be performed again. Alternatively, the conductive ink may be applied to one through micro-hole 81 a plurality of times (e.g., multiple applications), followed by the rotation of the drum 1 at the second rotational speed.

### Second Embodiment

Next, a conductive film forming apparatus according to a second embodiment will be described. The second embodiment will be described focusing on differences from the first embodiment, and descriptions of the same configurations may be omitted.

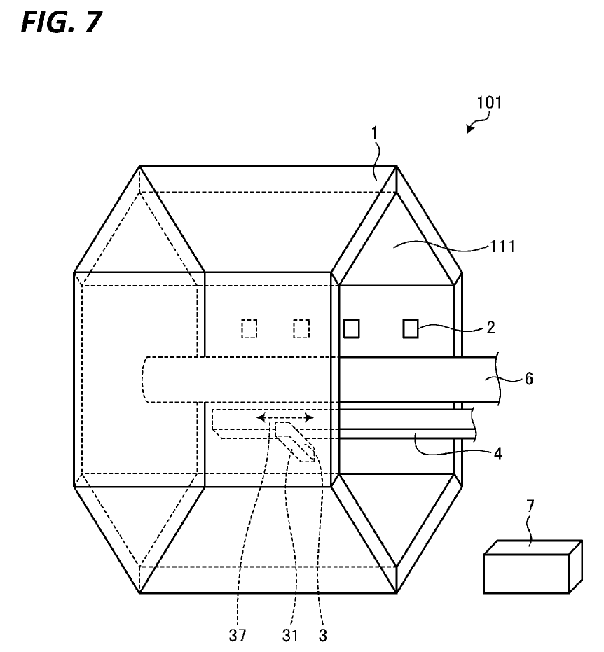

FIG. 7 is a schematic view illustrating the configuration of the conductive film forming apparatus according to the second embodiment. A conductive film forming apparatus 101 illustrated in FIG. 7 is provided by rotating the components of the conductive film forming apparatus 100 illustrated in FIG. 1, except for the control device 7, by 90 degrees relative to the floor surface. FIG. 7 omits the illustration of the lifting rail holding mechanism 5, the movement drive mechanism 9, and the rotation drive mechanism 10. Thus, the inkjet head 3 may move in the horizontal direction (e.g., the direction indicated by a double-headed arrow 37) rather than in the up-down direction, and the rotary shaft 6 extends in the horizontal direction rather than in the up-down direction. The conductive film forming apparatus 101 performs the same process as performed by the conductive film forming apparatus 100.

In the second embodiment, the ejection surface 31 of the inkjet head 3 is positioned to face downward in the vertical direction. That is, droplets of the conductive ink are ejected vertically downward from the inkjet head 3. As a result, as compared to the first embodiment, it is unnecessary to consider, for example, the hydraulic head difference between the tank of the supply side and the ejection surface 31 of the inkjet head 3, or the gravitational dripping of droplets adhering to the nozzle surface, when supplying the conductive ink to the inkjet head 3 or ejecting the conductive ink from the inkjet head 3.

During the process in which the inkjet head 3 ejects the conductive ink to apply the conductive ink onto the substrate 80, the substrate 80 onto which the application of the conductive ink has been completed may be positioned at the upper portion of the drum 1. However, since the ink ejected from the inkjet head 3 to the through micro-holes 81 is about one to three drops, and one drop of the ink is about 2 pL, the ink is very unlikely to move due to gravity, and there is no problem even though the substrate 80 is inverted. The holding unit 2 may securely hold the substrate 80 to prevent the substrate 80 from falling off the drum 1. For example, when the holding unit 2 holds the substrate 80 by adsorption, a stronger adsorption force than that in the first embodiment may be applied in the present embodiment.

After the ejection of the conductive ink to all of the substrates 80 (e.g., the application of the conductive ink) is completed, the control device 7 retracts the inkjet head 3 to a predetermined retracted position, rotates the components other than the control device 7 by 90 degrees relative to the floor surface (e.g., to stand upright) to be brought into the same state as in the first embodiment, and controls the rotation drive mechanism 10 to rotate the drum 1 at the second rotational speed. Alternatively, the control device 7 may control the rotation drive mechanism 10 to rotate the drum 1 at the second rotational speed, in the same state as that during the application of the conductive ink (e.g., maintaining the positions of the drum 1 and the inkjet head 3 illustrated in FIG. 7).

The conductive film forming apparatus 101 according to the second embodiment has been described. According to the conductive film forming apparatus 101 of the second embodiment, a uniform conductive film may be formed in the through micro-holes 81, as in the conductive film forming apparatus 100 of the first embodiment.

### Modifications to Drum

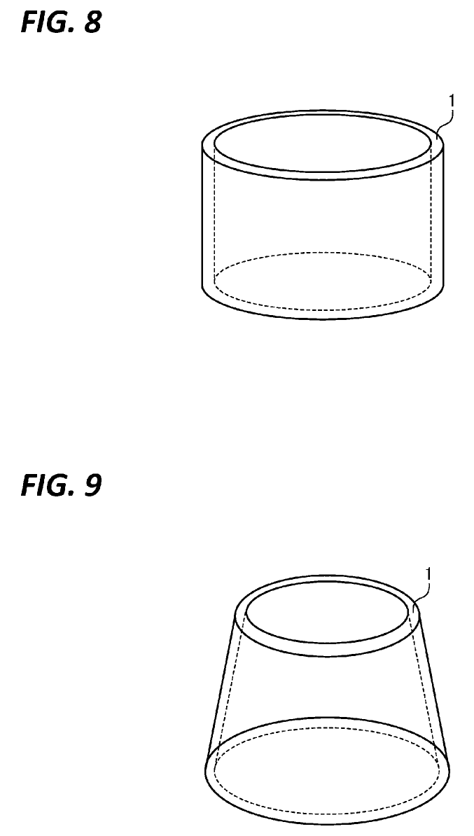

In the first and second embodiments, descriptions have been made on the case where the drum 1 provided in the conductive film forming apparatus 100, 101 has the prismatic shape, particularly, in which one end side thereof is covered by the hexagonal bottom surface 12. However, the bottom surface of the drum 1 may not have the hexagonal shape, and may have a polygonal shape such as a triangular, quadrilateral, or pentagonal shape. Further, the drum 1 may not have the prismatic shape, and may have a cylindrical shape in which one end side thereof is covered by a lid as illustrated in FIG. 8, or a conical shape in which an apex-side portion thereof is cut off to define an opening, and a cavity is formed inside as illustrated in FIG. 9. FIG. 8 is a schematic view illustrating the shape of the drum according to a modification. FIG. 9 is a schematic view illustrating the shape of the drum according to another modification.

In both of FIGS. 8 and 9, the positions corresponding to the first to sixth rotation positions described in the first embodiment (e.g., the positions where the drum 1 is stopped for the application from the inkjet head 3) may be set in advance by calculating predetermined ranges in which the conductive ink may be ejected from the inkjet head 3 to the through micro-holes 81, and determining positions corresponding to the predetermined ranges.

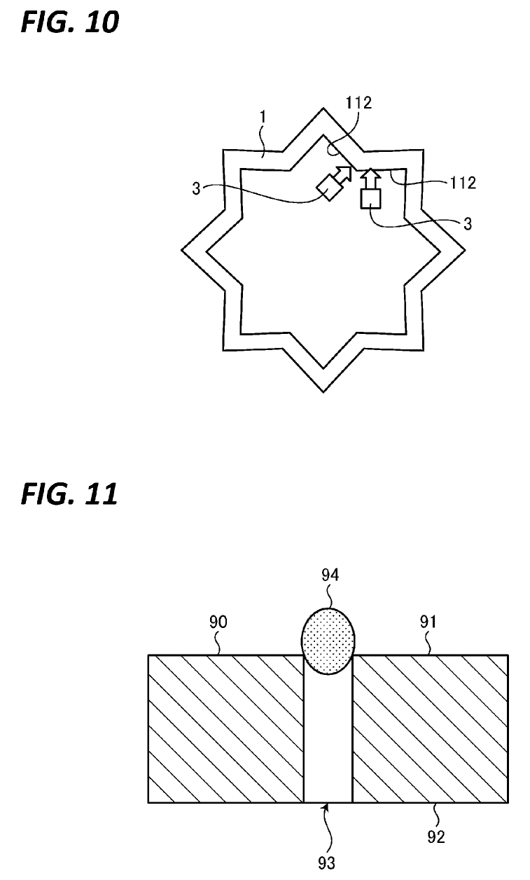

FIG. 10 is a plan view of a drum according to a modification. As illustrated in FIG. 10, the conductive film forming apparatus 100, 101 may include a plurality of inkjet heads 3 that ejects the conductive ink in different directions (e.g., in directions that are not parallel to each other), and further include a plurality of sets of planes 112, in which directions of normal vectors thereof coincide with ejection directions of a plurality of conductive inks from the plurality of inkjet heads 3, for each predetermined angular range (e.g., 45 degrees in the example of FIG. 10). Further, at least one holding unit 2 may be provided for each plane 112.

### Other Modifications to Drum

As a modification to the drum 1 according to the first embodiment, when ejecting the conductive ink to the plurality of through micro-holes 81 of the substrate 80, all of the six planes 111 may be arranged to be parallel to the horizontal plane. That is, the drum 1 may have a shape unfolded around the bottom surface 12. The six planes 111 are arranged on the horizontal plane in the state where the lower ends thereof are in contact with the sides of the bottom surface 12, respectively. As illustrated in FIG. 7, the inkjet head 3 is disposed such that the ejection surface 31 is parallel to the floor surface. In this state, the inkjet head 3 ejects the conductive ink from above to the plurality of through micro-holes 81 of the substrates 80 held by the holding units 2 of each plane 111. That is, droplets of the conductive ink from the inkjet head 3 are ejected vertically downward. As a result, as compared to the first embodiment, it is unnecessary to consider, for example, the hydraulic head difference between the tank of the supply side and the ejection surface 31 of the inkjet head 3, or the gravitational dripping of droplets adhering to the nozzle surface, when supplying the conductive ink to the inkjet head 3 or ejecting the conductive ink from the inkjet head 3.

Then, after the ejection of the conductive ink to the plurality of through micro-holes 81 of all of the substrates 80 is completed, the six plate-shaped members arranged on the horizontal plane are brought into the upright position to assemble a prismatic member that has a hexagonal shape in plan view (e.g., the drum 1). After the drum 1 is assembled, the drum 1 is rotated at the second rotational speed as in the first embodiment.

Further, the six planes 111 may be arranged on the horizontal plane in the state where each plane 111 is connected to its adjacent plane 111 at the side shared therebetween. The bottom surface 12 may be connected to the lower end of any one of the planes 111, or disposed separately from the six planes 111. When ejecting the conductive ink to the plurality of through micro-holes 81 of the substrate 80, the six planes 111 are arranged to be parallel to the horizontal plane, and as illustrated in FIG. 7, the inkjet head 3 may be positioned in the state where the ejection surface 31 becomes parallel to the floor surface. In this state, the inkjet head 3 ejects the conductive ink from above to the plurality of through micro-holes 81 of the substrates 80 held by the holding units 2 of each plane 111. That is, droplets of the conductive ink from the inkjet head 3 are ejected vertically downward. Thus, in this case as well, as compared to the first embodiment, it is unnecessary to consider, for example, the hydraulic head difference between the tank of the supply side and the ejection surface 31 of the inkjet head 3, or the gravitational dripping of droplets adhering to the nozzle surface, when supplying the conductive ink to the inkjet head 3 or ejecting the conductive ink from the inkjet head 3.

After the ejection of the conductive ink to all of the plurality of through micro-holes 81 in all of the substrates 80 is completed, each of the six plate-shaped members including the six planes 111 is arranged with respect to the member including the bottom surface 12, such that the angle between the bottom surface 12 and each of the six planes 111 becomes 90 degrees. As a result, the drum 1 is assembled. After the drum 1 is assembled, the drum 1 is rotated at the second rotational speed as in the first embodiment.

### Other Modifications

In the embodiments described above, for example, the substrate 80 is provided in parallel to the plane 111. However, the present disclosure is not limited thereto. When the direction of the centrifugal force acting on the substrate 80 held on the inner peripheral surface 11 due to the rotation of the drum 1 coincides with the direction in which the through micro-holes 81 formed in the substrate 80 extend, the ink may be most efficiently filled into the through micro-holes 81. That is, when the through micro-holes 81 are formed to be perpendicular to the main surfaces 82 and 83, the substrate 80 may be arranged such that the main surfaces 82 and 83 become parallel to the plane 111. When the through micro-holes 81 are not formed to be perpendicular to the main surfaces 82 and 83, the substrate 80 may be disposed such that the direction in which the through micro-holes 81 extend coincides with the direction of the centrifugal force acting on the substrate 80 due to the rotation of the drum 1.

In the embodiments described above, for example, the pitch between the nozzles of the inkjet head 3 coincides with the pitch of the through micro-holes 81 formed in the substrate 80, or has the integer multiple relationship therewith. However, the present disclosure is not limited thereto. When the pitch between the nozzles of the inkjet head 3 does not coincide with the pitch of the through micro-holes 81, or does not have the integer multiple relationship therewith, the ink may be ejected while moving the inkjet head 3 and the drum 1 relatively along the rotation direction of the drum 1, thereby making the positions of the nozzles of the inkjet head 3 to coincide with the positions of the through micro-holes 81.

While the embodiments of the present disclosure have been described, the embodiments are merely illustrative, and are not intended to limit the scope of the invention. The embodiments may be implemented in other various forms, and various omissions, substitutions, modifications, and combinations may be made without departing from the gist of the invention. The embodiments and the modifications thereto are included in the scope or gist of the invention, and are also included in the scope of the invention set forth in the claims and equivalents thereof.

What is claimed is:

1. A conductive film forming apparatus comprising:
a drum including an inner peripheral surface that forms a hollow structure, and a holder provided in the inner peripheral surface and configured to hold a substrate;
an inkjet head configured to eject conductive ink;
a rotation driver configured to rotate the drum; and
a controller configured to control the inkjet head to eject the conductive ink to a plurality of through micro-holes formed in the substrate, and after ejection of the conductive ink by the inkjet head is completed, to control the rotation driver to rotate the drum.

2. The conductive film forming apparatus according to claim 1, further comprising:
a movement mechanism including a motor and configured to relatively move the inkjet head with respect to the drum in a direction different from a direction of movement by the rotation driver,
wherein the controller
causes the movement mechanism to relatively move the inkjet head with respect to the drum such that the inkjet head ejects the conductive ink to all of the plurality of through micro-holes of the substrate held by the holder, and
by relatively moving the inkjet head with respect to the drum, completes the ejection of the conductive ink by the inkjet head.

3. The conductive film forming apparatus according to claim 1, wherein a plurality of holders is provided on the inner peripheral surface,
a plurality of substrates forms a substrate group in each range corresponding to a predetermined angle of the inner peripheral surface,
the predetermined angle is set in advance in a rotation direction of the drum, a plurality of substrate groups is arranged in the rotation direction of the drum, and
the controller is configured to:
repeatedly control the rotation driver to rotate the drum by the predetermined angle at a first rotational speed, and then, stop the drum such that when the drum stops, an ejection surface of the inkjet head faces the substrate group corresponding to the predetermined angle,
control the rotation driver and the inkjet head such that each time the drum stops, the conductive ink is ejected to the plurality of through micro-holes of the substrate group, and
after the ejection of the conductive ink to all of the substrate groups is completed, cause the rotation driver to rotate the drum at a second rotational speed faster than the first rotational speed.

4. The conductive film forming apparatus according to claim 1, wherein the drum has a prismatic shape in which one end side thereof is covered by a lid, a cylindrical shape in which one end side thereof is covered by a lid, or a conical shape in which an apex-side portion thereof is cut off to define an opening, the conical shape having a cavity therein.

5. The conductive film forming apparatus according to claim 1, wherein a liquid repellent layer is formed on a surface of the substrate that faces the inkjet head, and
the controller causes the inkjet head to eject the conductive ink from a side of the liquid repellent layer to the plurality of through micro-holes of the substrate on which the liquid repellent layer is formed.

6. A conductive film forming method comprising:
ejecting conductive ink to a plurality of through micro-holes formed in a plate-shaped substrate including a first surface and a second surface opposite to the first surface, from a side of the first surface; and
moving the substrate such that a force is applied to the conductive ink adhering to the substrate in a direction from the first surface toward the second surface.
